(19) United States
(12) Patent Application Publication
(10) Pub. No.: US 2023/0187261 A1
(43) Pub. Date: Jun. 15, 2023

(54) WAFER PLACEMENT TABLE

(71) Applicant: NGK Insulators, Ltd., Nagoya-City (JP)

(72) Inventors: Hiroya SUGIMOTO, Chiryu-City (JP); Masaki ISHIKAWA, Handa-City (JP)

(73) Assignee: NGK Insulators, Ltd., Nagoya-City (JP)

(21) Appl. No.: 18/048,486

(22) Filed: Oct. 21, 2022

(30) Foreign Application Priority Data
Dec. 15, 2021 (JP) 2021-203468

(51) Int. Cl. H01L 21/687; H01L 21/67; H05B 3/28; H05B 3/14; H05B 3/03

(52) U.S. Cl. CPC H01L 21/68757; H01L 21/67103; H05B 3/283; H05B 3/143; H05B 3/03

(57) ABSTRACT

A wafer placement table includes a ceramic substrate having a wafer placement surface; a first electrically conductive layer embedded in the ceramic substrate; and an electrically conductive via connected at one end to the first electrically conductive layer, wherein the electrically conductive via includes a plurality of columnar members connected together in a vertical direction, and wherein the area of the connection surface of one of two columnar members connected to each other is larger than the area of the connection surface of the other.

### BACKGROUND OF THE INVENTION

### 1. Field of the Invention

The present invention relates to a wafer placement table.

### 2. Description of the Related Art

One previously known wafer placement table includes a ceramic substrate having a wafer placement surface, an electrically conductive layer embedded in the ceramic substrate, and electrically conductive vias connected to the electrically conductive layer. For example, in a wafer placement table disclosed in PTL 1, resistance heating elements provided for respective zones and multi-stage jumper wires that supply electric power to the respective resistance heating elements are arranged in this order from the wafer placement surface side and embedded in the ceramic substrate. The wafer placement table further includes electrically conductive vias that connect the resistance heating elements to the jumper wires in the vertical direction. The resistance heating elements and the jumper wires correspond to their respective electrically conductive layers. A multilayer structure body is often used for the ceramic substrate in the above wafer placement table. In this case, the electrically conductive vias are each formed by connecting two upper and lower columnar members together.

### CITATION LIST

### Patent Literature

PTL 1: WO 2021/054322 A1

### SUMMARY OF THE INVENTION

When the ceramic substrate is a multilayer structure body, columnar members in layers vertically adjacent to each other are connected together in a process of producing the wafer placement table. However, when columnar members offset from each other are connected together, the area of contact between the connected portions is smaller, and this may cause the electrically conductive vias to generate heat. The generation of heat by the electrically conductive vias is not preferred because the thermal uniformity of the wafer deteriorates.

The present invention has been made to solve the foregoing problem, and it is a principal object to reduce the generation of heat by the electrically conductive vias.

A first wafer placement table of the present invention includes: a ceramic substrate having a wafer placement surface; a first electrically conductive layer embedded in the ceramic substrate; and an electrically conductive via connected at one end to the first electrically conductive layer, wherein the electrically conductive via includes a plurality of columnar members connected together in a vertical direction, and wherein the area of the connection surface of one of two columnar members connected to each other is larger than the area of the connection surface of the other.

In this wafer placement table, the electrically conductive via includes the plurality of columnar members connected together in the vertical direction. The area of the connection surface of a first one of two columnar members connected to each other is larger than the area of the connection surface of a second one of the two columnar members. In this case, when two columnar members vertically adjacent to each other are connected to each other, even if a first one of the two columnar members is offset from a second one of the columnar members, the connection surface having a larger area absorbs the offset, so that a sufficient contact area can be provided between the connection surfaces. Therefore, the generation of heat by the electrically conductive via can be reduced.

In the first wafer placement table of the present invention, the ceramic substrate may be a multilayer structure body, and the connection surface of each of the columnar members may be located between corresponding layers of the multilayer structure body. In the multilayer structure body used as the ceramic substrate, since layer-to-layer misalignment is likely to occur, it is highly significant to apply the present invention to this ceramic substrate.

In the first wafer placement table of the present invention, the plurality of columnar members may contain the same ceramic material as a ceramic material contained in the ceramic substrate, and the content of the ceramic material in the first one of the two columnar members connected to each other that has the connection surface having a larger area may be larger than the content of the ceramic material in the second one of the two columnar members that has the connection surface having a smaller area. In this case, the occurrence of cracking can be reduced.

A second wafer placement table of the present invention includes: a ceramic substrate having a wafer placement surface; a first electrically conductive layer embedded in the ceramic substrate; and an electrically conductive via connected at a first end to the first electrically conductive layer, wherein the electrically conductive via includes a plurality of columnar members connected together in a vertical direction, wherein an intermediate member having an upper surface and a lower surface is joined between mutually connected two of the columnar members, wherein the area of the upper surface of the intermediate member is larger than the area of a connection surface of the columnar member joined to the upper surface of the intermediate member, wherein the area of the lower surface of the intermediate member is larger than the area of a connection surface of the columnar member joined to the lower surface of the intermediate member, and wherein the intermediate member has a thickness of 0.1 mm or more.

In this wafer placement table, the electrically conductive via includes the plurality of columnar members connected together in the vertical direction. The intermediate member is joined between the mutually connected two of the columnar members. The area of the upper surface of the intermediate member is larger than the area of the connection surface of the columnar member joined to the upper surface of the intermediate member, and the area of the lower surface of the intermediate member is larger than the area of the connection surface of the columnar member joined to the lower surface of the intermediate member. Therefore, when two columnar members vertically adjacent to each other are connected to each other, even if a first one of the two columnar members is offset from a second one of the columnar members, the intermediate member absorbs the offset, so that a sufficient contact area can be provided between the connection portions. Moreover, since the thickness of the intermediate member is 0.1 mm or more, heat generation due to an electric current flowing through the intermediate member can be reduced. Therefore, the generation of heat by the via can be reduced.

In the second wafer placement table of the present invention, the ceramic substrate may be a multilayer structure body, and the intermediate member may be located between layers of the multilayer structure body. In the multilayer structure body used as the ceramic substrate, since layer-to-layer misalignment is likely to occur, it is highly significant to apply the present invention to this ceramic substrate.

In the second wafer placement table of the present invention, the plurality of columnar members and the intermediate member may contain the same ceramic material as a ceramic material contained in the ceramic substrate, and the content of the ceramic material in the intermediate member may be larger than the content of the ceramic material in the mutually connected two of the columnar members. In this manner, the occurrence of cracking can be reduced.

In the first and second wafer placement tables of the present invention, the ceramic substrate may include a second electrically conductive layer disposed thereinside and located on a lower side of the first electrically conductive layer, and the electrically conductive via may be connected at a second end to the second electrically conductive layer. In this manner, the generation of heat by the electrically conductive via embedded in the ceramic substrate can be prevented.

In the first and second wafer placement tables of the present invention, a first one of the first electrically conductive layer and the second electrically conductive layer may be a heater electrode formed from a resistance heating element, and a second one of the first electrically conductive layer and the second electrically conductive layer may be a jumper layer. In this case, each wafer placement table has a heater function, and the generation of heat by the via can be reduced. The heater electrode may include a plurality of heater electrodes provided for respective zones of the ceramic substrate, and the jumper layer may include a plurality of jumper layers disposed in the ceramic substrate.

### BRIEF DESCRIPTION OF THE DRAWINGS

FIG. 1 is a plan view of a wafer placement table 10.

FIG. 2 is a cross-sectional view taken along A-A in FIG. 1.

FIG. 3 is a cross-sectional view when the wafer placement table 10 cut along the upper surface of a third ceramic layer 23 is viewed from above.

FIG. 4 is a cross-sectional view when the wafer placement table 10 cut along the upper surface of a second ceramic layer 22 is viewed from above.

FIG. 5 is a cross-sectional view when the wafer placement table 10 cut along the upper surface of a first ceramic layer 21 is viewed from above.

FIGS. 6A and 6B are illustrations of inner vias 54 when they are viewed from below.

FIGS. 7A to 7C are production process diagrams of the wafer placement table 10.

FIGS. 8A to 8C are vertical cross-sectional views of inner vias 64.

### DETAILED DESCRIPTION OF THE INVENTION

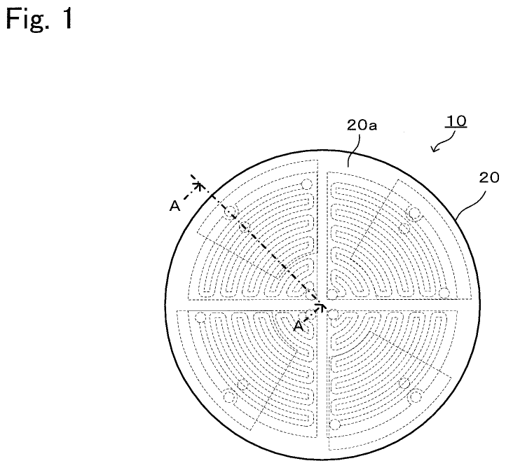

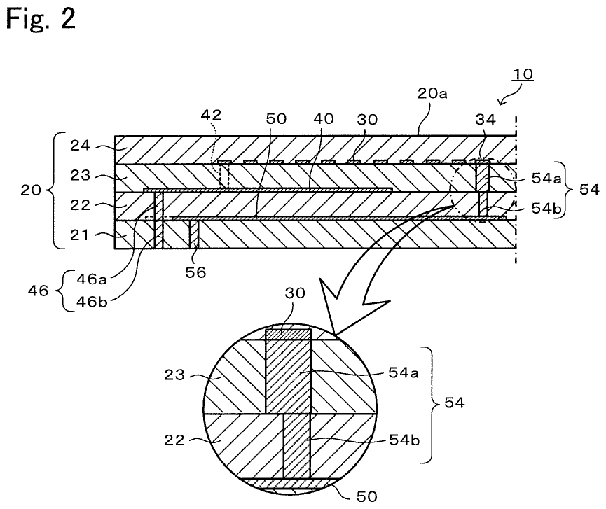

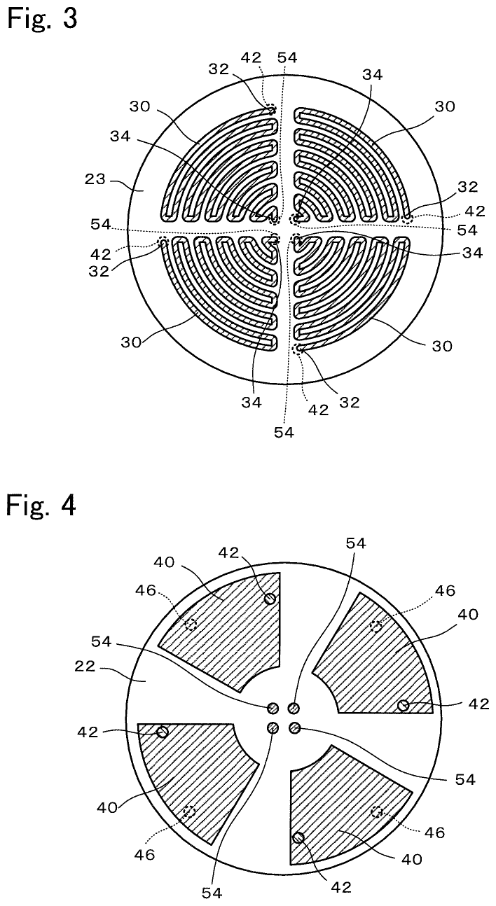

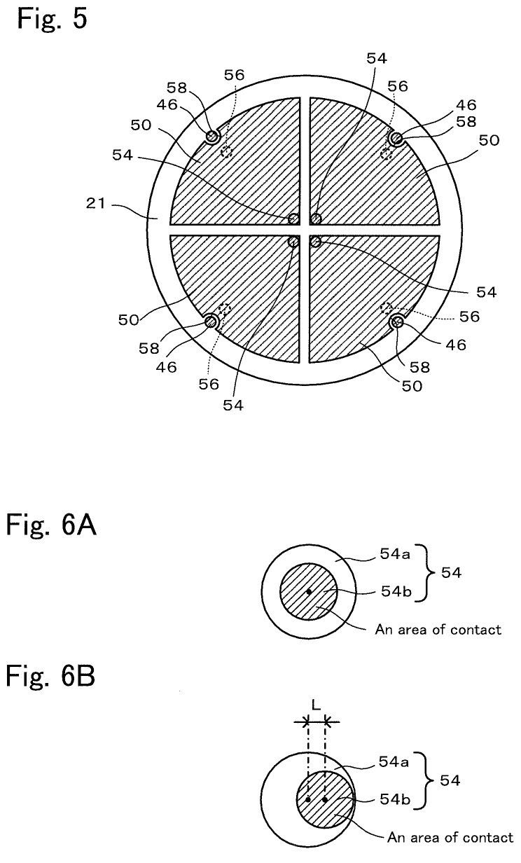

Preferred embodiments of the present invention will be described with reference to the drawings. FIG. 1 is a plan view of a wafer placement table 10, and FIG. 2 is a cross-sectional view taken along A-A in FIG. 1. FIGS. 3 to 5 are cross-sectional views when the wafer placement table 10 cut in the horizontal direction is viewed from above. In the following description, up-down, right-left, and front-rear may be used. However, these up-down, right-left, and front-rear merely represent relative positional relations.

The wafer placement table 10 includes a ceramic substrate 20 and further includes heater electrodes 30, upper jumper layers 40, and lower jumper layers 50 that are embedded in the ceramic substrate 20.

The ceramic substrate 20 is a ceramic-made circular disk and has, as its upper surface, a wafer placement surface 20a for placement of a wafer. Examples of the ceramic include alumina and aluminum nitride. The ceramic substrate 20 is a multilayer structure body. In the present embodiment, the ceramic substrate 20 includes first to fourth ceramic layers 21 to 24 stacked from bottom to top as shown in FIG. 2.

The heater electrodes 30 are disposed on the upper surface of the third ceramic layer 23. The heater electrodes 30 are disposed in respective zones. These zones are obtained by dividing the circular shape of the third ceramic layer 23 in plan view into a plurality of sectors (four sectors in the present embodiment). Each of the heater electrodes 30 is formed by placing a resistance heating element in a one-stroke pattern extending from an outer circumferential edge 32 to a center edge 34 over the entire region of the corresponding sector zone. The heater electrodes 30 are formed from a material mixture of a metal and a ceramic. Examples of the metal include Ru, W, and Mo, and a metal having a thermal expansion coefficient close to that of the ceramic substrate 20 is preferred. The ceramic used is the same as the material of the ceramic substrate 20. Since the heater electrodes 30 are formed from the material mixture described above, for example, the occurrence of cracking between the heater electrodes 30 and the ceramic substrate 20 due to the difference in thermal expansion coefficient therebetween can be prevented.

Each of the upper jumper layers 40 has a flat shape and is disposed on the upper surface of the second ceramic layer 22. The upper jumper layers 40 are formed as four sector-shaped layers corresponding to the respective heater electrodes 30. The upper jumper layers 40 are connected to the outer circumferential edges 32 of the respective heater electrodes 30 through respective conductive inner vias 42. Each of the inner vias 42 passes vertically through the third ceramic layer 23. The inner vias 42 are connected at their upper ends to the outer circumferential edges 32 of the respective heater electrodes 30 and connected at their lower ends to the respective upper jumper layers 40. The upper ends of electrically conductive power supply vias 46 are connected to the respective upper jumper layers 40. Each of the power supply vias 46 includes an upper columnar member 46a and a lower columnar member 46b connected to each other in the vertical direction. The upper columnar member 46a passes vertically through the second ceramic layer 22, and the lower columnar member 46b passes vertically through the first ceramic layer 21. The lower end of the power supply via 46 is exposed at the lower surface of the ceramic substrate 20. The inner vias 42 and the power supply vias 46 may be formed, for example, of the same material as the material of the heater electrodes 30.

Each of the lower jumper layers 50 has a flat shape and is disposed on the upper surface of the first ceramic layer 21. The lower jumper layers 50 are formed as four sector-shaped layers corresponding to the respective heater electrodes 30. The lower jumper layers 50 are connected to the center edges 34 of the respective heater electrodes 30 through respective electrically conductive inner vias 54. Each of the inner vias 54 passes vertically through the second and third ceramic layers 22 and 23. The upper ends of the inner vias 54 are connected to the center edges 34 of the respective heater electrodes 30, and the lower ends of the inner vias 54 are connected to the respective lower jumper layers 50. The upper ends of electrically conductive power supply vias 56 are connected to the respective lower jumper layers 50. The power supply vias 56 pass vertically through the first ceramic layer 21. The lower ends of the power supply vias 56 are exposed at the lower surface of the ceramic substrate 20. Notches 58 are formed in the lower jumper layers 50 such that the lower jumper layers 50 do not come into contact with the power supply vias 46. The inner vias 54 and the power supply vias 56 may be formed, for example, of the same material as the material of the heater electrodes 30.

The inner vias 54 connect the lower surfaces of the center edges 34 of the heater electrodes 30 to the upper surfaces of the lower jumper layers 50. Each of the inner vias 54 includes an upper columnar member 54a and a lower columnar member 54b connected to each other in the vertical direction. The area of the connection surface (lower surface) of the upper columnar member 54a is larger than the area of the connection surface (upper surface) of the lower columnar member 54b. When the upper columnar member 54a and the lower columnar member 54b are connected to each other, even if one of the upper columnar member 54a and the lower columnar member 54b is offset from the other, the connection surface of the upper columnar member 54a absorbs the offset. Therefore, a sufficient contact area can be provided between the connection surfaces. For example, even if one of the upper columnar member 54a and the lower columnar member 54b connected to each other is offset from the other, the area of contact between these members 54a and 54b is unchanged, provided that the upper surface of the lower columnar member 54b does not protrude from the lower surface of the upper columnar member 54a. FIGS. 6A and 6B show schematic illustrations when inner vias 54 are viewed from below. FIG. 6A shows an inner via 54 when the upper columnar member 54a and the lower columnar member 54b are connected to each other with their axes not offset from each other, and FIG. 6B shows an inner via 54 when the upper columnar member 54a and the lower columnar member 54b are connected to each other with their axes offset from each other by distance L (L is the difference obtained by subtracting the radius of the lower columnar member 54b from the radius of the upper columnar member 54a). The area of contact between the connection surfaces when the axes of these members coincide with each other is indicated by a hatched portion in FIG. 6A, and the area of contact between the connection surfaces when the axes of these members are offset by distance L is indicated by a hatched portion in FIG. 6B. The areas of contact in these figures are the same. However, if these axes are offset by a distance larger than distance L, the area of contact between the connection surfaces decreases. Therefore, in the present embodiment, these axes are allowed to be offset by up to distance L.

When the large diameter upper columnar member 54a and the small diameter lower columnar member 54b are used, it is preferable to set the large and small diameters such that no cracking occurs in the ceramic substrate 20. For example, the small diameter may be set to, for example, from 0.5 mm to 1 mm inclusive. The lower limit of the large diameter may be set to the small diameter+0.2 mm, and the upper limit of the large diameter may be set to 2 mm. The ceramic content of the lower columnar member 54b (the ceramic is the same ceramic material as the ceramic contained in the ceramic substrate 20) may be from 3% by mass to 15% by mass inclusive. The lower limit of the ceramic content of the upper columnar member 54a may be the same as the ceramic content of the lower columnar member 54b, and the upper limit may be two times the ceramic content of the lower columnar member 54b. The ceramic content of the large diameter upper columnar member 54a may be larger than the ceramic content of the small diameter lower columnar member 54b.

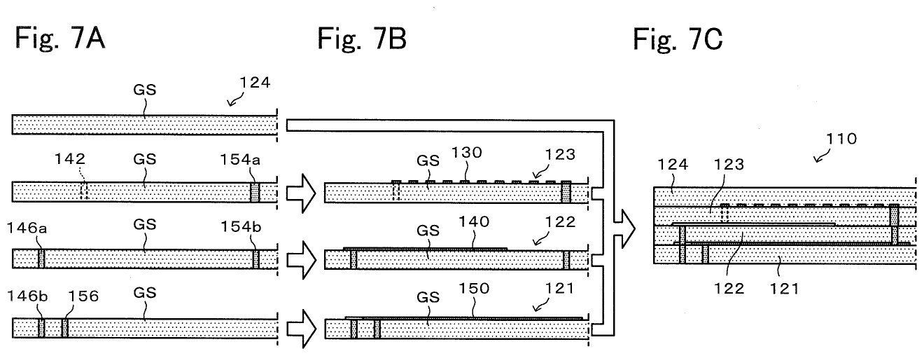

Next, a production example of the wafer placement table 10 will be described using FIGS. 7A to 7C. FIGS. 7A to 7C are production process diagrams of the wafer placement table 10. First, four disk-shaped ceramic green sheets GS are produced. The ceramic green sheets GS are produced by a tape casting method.

For the first ceramic green sheet GS, through holes are formed at positions corresponding to the lower columnar members 46b and the power supply vias 56, and the through holes are filled with an electrically conductive paste to form paste-filled portions 146b and 156 (see FIG. 7A). Then an electrically conductive paste is printed in the same pattern as the pattern of the lower jumper layers 50 on the upper surface of the ceramic green sheet GS to thereby form a lower jumper precursor 150, and a first sheet 121 is thereby obtained (see FIG. 7B).

For the second ceramic green sheet GS, through holes are formed at positions corresponding to the upper columnar members 46a and the lower columnar members 54b, and the through holes are filled with an electrically conductive paste to form paste-filled portions 146a and 154b (see FIG. 7A). Then an electrically conductive paste is printed in the same pattern as the pattern of the upper jumper layers 40 on the upper surface of the ceramic green sheet GS to thereby form an upper jumper precursor 140, and a second sheet 122 is thereby obtained (see FIG. 7B).

For the third ceramic green sheet GS, through holes are formed at positions corresponding to the inner vias 42 and the upper columnar members 54a, and the through holes are filled with an electrically conductive paste to form paste-filled portions 142 and 154a (see FIG. 7A). Then an electrically conductive paste is printed in the same pattern as the pattern of the heater electrodes 30 on the upper surface of the ceramic green sheet GS to thereby form a heater electrode precursor 130, and a third sheet 123 is thereby obtained (see FIG. 7B).

For the fourth ceramic green sheet GS, the sheet itself is used as a fourth sheet 124 (see FIG. 7A).

Then the first to fourth sheets 121 to 124 are stacked in this order from bottom to top to thereby obtain a layered body 110 (see FIG. 7C). The layered body 110 is fired to obtain the wafer placement table 10. When the first to fourth sheets 121 to 124 are stacked, the third sheet 123 and the second sheet 122 are occasionally stacked with the axes of the paste-filled portions 154a of the third sheet offset from the axes of the paste-filled portions 154b of the second sheet 122. However, since the connection surfaces of the paste-filled portions 154a are larger than the connection surfaces of the paste-filled portions 154b, some misalignment is allowed.

Next, a usage example of the wafer placement table 10 will be described. Heater power sources (not shown) are connected to the respective heater electrodes 30. Specifically, one of a pair of power supply terminals of each heater power source (the positive electrode of the heater power source) is connected to the power supply via 46 of the corresponding heater electrode 30, and the other one of the pair of power supply terminals of the heater power source (the negative electrode of the heater power source) is connected to the power supply via 56 of the heater electrode 30. Then a wafer is placed on the wafer placement surface 20a, and electric power is supplied separately to the heater electrodes 30 to heat the wafer. In this case, the electric power is supplied such that the entire wafer is at the same temperature. The wafer in this state is subjected to processing.

Next, the correspondences between the components in the present embodiment and the components in the present invention will be clarified. The ceramic substrate 20 in the present embodiment corresponds to the ceramic substrate in the present invention, and each of the heater electrodes 30 corresponds to the first electrically conductive layer. Each of the inner vias 54 corresponds to the electrically conductive via. The upper and lower columnar members 54a and 54b correspond to the columnar members, and each of the lower jumper layers 50 corresponds to the second electrically conductive layer.

In the above-described wafer placement table 10 in the present embodiment, each inner via 54 includes the corresponding upper columnar member 54a and the corresponding lower columnar member 54b connected to each other in the vertical direction, and the area of the connection surface (lower surface) of the upper columnar member 54a is larger than the area of the connection surface (upper surface) of the lower columnar member 54b. Therefore, when two columnar members vertically adjacent to each other are connected to each other, even if one of the columnar members is offset from the other, the connection surface having a larger area absorbs the offset. This allows a sufficient contact area to be provided between the connection surfaces. Therefore, the generation of heat by the inner via 54 can be reduced, and the thermal uniformity of the wafer is improved.

The connection portion between the upper columnar member 54a and the lower columnar member 54b is located between layers (the second ceramic layer 22 and the third ceramic layer 23) of the ceramic substrate 20, i.e., a multilayer structure body. In this ceramic substrate 20, since layer-to-layer misalignment is likely to occur, it is highly significant to apply the present invention to the ceramic substrate 20.

Moreover, the ceramic content of the large diameter upper columnar member 54a may by larger than the ceramic content of the small diameter lower columnar member 54b. In this manner, the occurrence of cracking can be efficiently prevented without deterioration in the resistance of the inner via 54.

The present invention is not limited to the above-described embodiment. It will be appreciated that the present invention can be embodied in various forms so long as they fall within the technical scope of the invention.

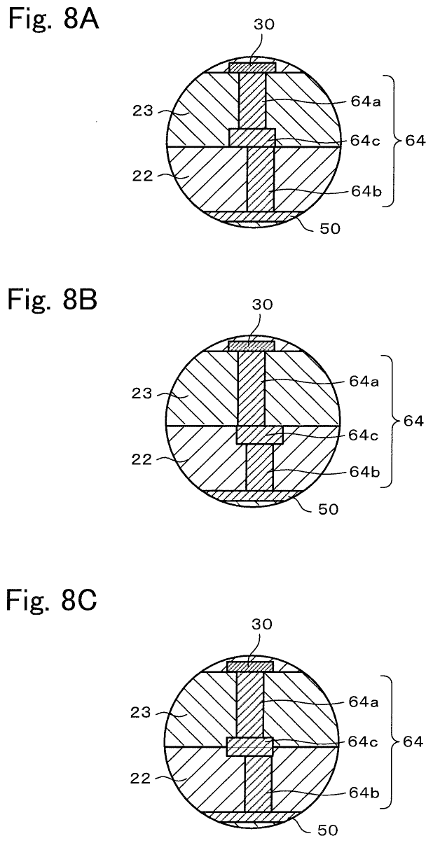

For example, in the embodiment described above, inner vias 64 shown in FIGS. 8A to C may be used instead of the inner vias 54. Each inner via 64 connects the corresponding heater electrode 30 to the corresponding lower jumper layer 50. Each inner via 64 includes an upper columnar member 64a and a lower columnar member 64b connected to each other in the vertical direction, and an intermediate member 64c having an upper surface and a lower surface is joined between the upper columnar member 64a and the lower columnar member 64b. The area of the upper surface of the intermediate member 64c is larger than the area of the connection surface of the upper columnar member 64a joined to the upper surface of the intermediate member 64c. Moreover, the area of the lower surface of the intermediate member 64c is larger than the area of the connection surface of the lower columnar member 64b joined to the lower surface of the intermediate member 64c. Therefore, even if the intermediate member 64c and the upper columnar member 64a are offset from each other, the upper surface of the intermediate member 64c absorbs the offset, so that a sufficient contact area can be provided between these members. Moreover, even if the intermediate member 64c and the lower columnar member 64b are offset from each other, the lower surface of the intermediate member 64c absorbs the offset, so that a sufficient contact area can be provided between these members. The thickness of the intermediate member 64c is preferably 0.1 mm or more. In this case, heat generation due to an electric current flowing through the intermediate member 64c can be reduced, and therefore the generation of heat by the inner via 54 can be reduced. From the viewpoint of preventing the occurrence of cracking around the intermediate member 64c, the thickness of the intermediate member 64c is preferably 1 mm or less. As for the numerical range of the outer diameter of the intermediate member 64c, the lower limit is preferably a value obtained by adding 0.2 mm to the outer diameter of the upper or lower columnar member 64a or 64b, and the upper limit is preferably 2 mm. The ceramic content of the intermediate member 64c may be larger than the ceramic content of the upper columnar member 64a and the ceramic content of the lower columnar member 54b. In this manner, the occurrence of cracking can be further prevented.

The intermediate member 64c is disposed between layers (between the second ceramic layer 22 and the third ceramic layer 23 in this case). However, the intermediate member 64c may be embedded in the third ceramic layer 23 as shown in FIG. 8A or may be embedded in the second ceramic layer 22 as shown in FIG. 8B, or first and second approximately equal halves of the intermediate member 64c may be embedded in the second and third ceramic layers 22 and 23, respectively, as shown in FIG. 8C.

In the embodiment described above, each inner via 54 passing vertically through two ceramic layers (the second and third ceramic layers 22 and 23) is formed by connecting two columnar members (the upper and lower columnar members 54a and 54b), but this is not a particular limitation. For example, an electrically conductive via passing vertically through a prescribed number of (three or more) ceramic layers may be formed by connecting the same number of columnar members as the prescribed number of ceramic layers. In this case, it is only necessary that the area of the connection surface of one of two columnar members connected to each other be larger than the area of the connection surface of the other.

In the embodiment described above, each inner via 54 includes the corresponding large diameter upper columnar member 54a and the corresponding small diameter lower columnar member 54b. However, the upper columnar member 54a may have a smaller diameter, and the lower columnar member 54b may have a larger diameter. Alternatively, a truncated conical member may be used instead of the upper columnar member 54a. In this case, the lower surface of the truncated conical member may be larger than the upper surface of the lower columnar member 54b, and the upper surface of the truncated conical member may be smaller than its lower surface.

In the embodiment described above, the power supply vias 46 may be formed similarly to the inner vias 54. Specifically, one of the upper and lower columnar members 46a and 46b of each power supply via 46 may have a larger diameter, and the other may have a smaller diameter. In this case, the power supply via 46 and the upper jumper layers 40 correspond to the electrically conductive via and the first electrically conductive layer, respectively, in the present invention. In this manner, even if one of the upper and lower columnar members 46a and 46b is offset from the other, the offset can be absorbed to some extent, so that the generation of heat by the power supply via 46 can be reduced.

In the embodiment described above, the ceramic substrate 20 may include an electrostatic chuck electrode disposed at a position close to the wafer placement surface 20a. The electrostatic chuck electrode is connected to a DC power source. By applying a DC voltage to the electrostatic chuck electrode, a wafer placed on the wafer placement surface 20a is sucked and fixed to the wafer placement surface 20a. The ceramic substrate 20 may include therein an RF electrode for plasma generation.

In the embodiment described above, the wafer placement table 10 may have a plurality of holes passing vertically through the wafer placement table 10. Examples of these holes include a plurality of gas holes having openings on the wafer placement surface 20a and lift pin holes for insertion of lift pins that move a wafer up and down with respect to the wafer placement surface 20a.

In the embodiment described above, a seal band may be disposed along the outer circumferential edge of the wafer placement surface 20a, and a plurality of small protrusions (flattened circular protrusions) may be provided in a region inside the seal band. In this case, the seal band and the plurality of small protrusions are disposed such that the top face of the seal band is flush with the top faces of the plurality of small protrusions. The wafer is supported by the top face of the seal band and the top faces of the plurality of small protrusions.

In the embodiment described above, the ceramic green sheets GS are used to produce the ceramic substrate 20, but this is not a particular limitation. For example, ceramic molded bodies obtained by packing ceramic powders may be used, or ceramic molded bodies produced by a mold casting method may be used. A combination of these methods may also be used.

The present application claims priority from Japanese Patent Application No. 2021-203468 filed Dec. 15, 2021, the entire contents of which are incorporated herein by reference.

What is claimed is:

1. A wafer placement table comprising:
a ceramic substrate having a wafer placement surface;
a first electrically conductive layer embedded in the ceramic substrate; and
an electrically conductive via connected at one end to the first electrically conductive layer,
wherein the electrically conductive via includes a plurality of columnar members connected together in a vertical direction, and
wherein the area of the connection surface of one of two columnar members connected to each other is larger than the area of the connection surface of the other.

2. The wafer placement table according to claim 1,
wherein the ceramic substrate is a multilayer structure body, and
wherein the connection surface of each of the columnar members is located between corresponding layers of the multilayer structure body.

3. The wafer placement table according to claim 1,
wherein the plurality of columnar members contain the same ceramic material as a ceramic material contained in the ceramic substrate, and
wherein the content of the ceramic material in the one of the two columnar members connected to each other that has the connection surface having a larger area is larger than the content of the ceramic material in the other that has the connection surface having a smaller area.

4. A wafer placement table comprising:
a ceramic substrate having a wafer placement surface;
a first electrically conductive layer embedded in the ceramic substrate; and
an electrically conductive via connected at one end to the first electrically conductive layer,
wherein the electrically conductive via includes a plurality of columnar members connected together in a vertical direction,
wherein two columnar members connected to each other are joined via an intermediate member having an upper surface and a lower surface,
wherein the area of the upper surface of the intermediate member is larger than the area of a connection surface of the columnar member joined to the upper surface of the intermediate member, wherein the area of the lower surface of the intermediate member is larger than the area of a connection surface of the columnar member joined to the lower surface of the intermediate member, and wherein the intermediate member has a thickness of 0.1 mm or more.

5. The wafer placement table according to claim 4,
wherein the ceramic substrate is a multilayer structure body, and
wherein the intermediate member is located between layers of the multilayer structure body.

6. The wafer placement table according to claim 4,
wherein the plurality of columnar members and the intermediate member contain the same ceramic material as a ceramic material contained in the ceramic substrate, and
wherein the content of the ceramic material in the intermediate member is larger than the content of the ceramic material in each of two of the columnar members connected to each other.

7. The wafer placement table according to claim 1,
wherein the ceramic substrate includes a second electrically conductive layer disposed therein and located on a lower side of the first electrically conductive layer, and
wherein the electrically conductive via is connected at the other end to the second electrically conductive layer.

8. The wafer placement table according to claim 7,
wherein one of the first electrically conductive layer and the second electrically conductive layer is a heater electrode formed from a resistance heating element, and the other is a jumper layer.

9. The wafer placement table according to claim 6,
wherein the ceramic substrate includes a second electrically conductive layer disposed therein and located on a lower side of the first electrically conductive layer, and
wherein the electrically conductive via is connected at the other end to the second electrically conductive layer.

10. The wafer placement table according to claim 9,
wherein one of the first electrically conductive layer and the second electrically conductive layer is a heater electrode formed from a resistance heating element, and the other is a jumper layer.
